(19) United States
(12) Patent Application Publication
(10) Pub. No.: US 2024/0421102 A1
(43) Pub. Date: Dec. 19, 2024

(54) MICROELECTRONIC ASSEMBLIES INCLUDING A MOLD MATERIAL WITH A STRESS-RELIEF TRENCH

(71) Applicant: Intel Corporation, Santa Clara, CA (US)

(72) Inventors: Chunqing Peng, Chandler, AZ (US); Tony Dambrauskas, Chandler, AZ (US); Mohan Yasodharababu, Phoenix, AZ (US); Yuvraj Singh, Chandler, AZ (US); Praneeth Nampally, Chandler, AZ (US); Robert Stingel, Gilbert, AZ (US)

(73) Assignee: Intel Corporation, Santa Clara, CA (US)

(21) Appl. No.: 18/334,572

(22) Filed: Jun. 14, 2023

(51) Int. Cl. H01L 23/00; H01L 23/16; H01L 23/31; H01L 25/065

(52) U.S. Cl. CPC H01L 23/562; H01L 23/16; H01L 23/3107; H01L 25/0652; H01L 24/16; H01L 24/17; H01L 24/32; H01L 24/33; H01L 24/73; H01L 2224/16145; H01L 2224/16227; H01L 2224/17181; H01L 2224/32145; H01L 2224/32225; H01L 2224/33181; H01L 2224/73204

(57) ABSTRACT

Disclosed herein are microelectronic assemblies, as well as related apparatuses and methods. In some embodiments, a microelectronic assembly may include a first die having a first surface, an opposing second surface, and a first footprint; a second die electrically coupled to the second surface of the first die and having a second footprint, wherein the second footprint is smaller than the first footprint; and a mold material on the second surface of the first die and surrounding the second die, the mold material including a trench.

### BACKGROUND

Package substrates in integrated circuit (IC) packages are traditionally used to route electrical connections between a die and a circuit board. Dies and other functional components and elements may be coupled to a base die and then the base die may be coupled to a package substrate. During coupling, the dies may be exposed to high temperatures and may experience warpage, which may cause failures.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1A is a top view of an exemplary microelectronic assembly, in accordance with various embodiments.

FIG. 1B is a perspective view of a portion of the exemplary microelectronic assembly of FIG. 1A, in accordance with various embodiments.

FIG. 1C is a side, cross-sectional view of an exemplary microelectronic assembly along the A-A′ line of FIG. 1A, in accordance with various embodiments.

FIGS. 2A-2D are top views of other exemplary microelectronic assemblies, in accordance with various embodiments.

FIGS. 3A-3F are top views of exemplary trench arrangements in microelectronic assemblies, in accordance with various embodiments.

FIGS. 4A-4E are side, cross-sectional views of various stages in an example process for manufacturing the microelectronic assembly of FIG. 1C, in accordance with various embodiments.

FIG. 5 is a flow diagram of an example method of manufacturing a microelectronic assembly, in accordance with various embodiments.

FIG. 6 is a top view of a wafer and dies that may be included in a microelectronic assembly, in accordance with any of the embodiments disclosed herein.

FIG. 7 is a cross-sectional side view of an IC device that may be included in a microelectronic assembly, in accordance with any of the embodiments disclosed herein.

FIG. 8 is a cross-sectional side view of an IC device assembly that may include a microelectronic assembly, in accordance with any of the embodiments disclosed herein.

FIG. 9 is a block diagram of an example electrical device that may include a microelectronic assembly, in accordance with any of the embodiments disclosed herein.

### DETAILED DESCRIPTION

Disclosed herein are microelectronic assemblies, as well as related apparatuses and methods. In some embodiments, a microelectronic assembly may include a first die having a first surface, an opposing second surface, and a first footprint; a second die electrically coupled to the second surface of the first die and having a second footprint, wherein the second footprint is smaller than the first footprint; and a mold material on the second surface of the first die and surrounding the second die, the mold material including a trench.

Packaging semiconductor devices presents several challenges. One such challenge is encountered with the demand for miniaturization of semiconductor devices, which has led to an industry push toward die disaggregation since meeting smaller form factors on large, monolithic dies is increasingly difficult. Multi-die IC packaging typically requires increased die stacking and multiple thermal processing steps. The resulting IC packages may suffer from warpage generated as a result of the mismatch in the coefficient of thermal expansion (CTE) between a die and an encapsulating mold material. Fabrication of an IC package, is a multi-step process, which may include fabricating sub-assemblies that are incorporated into an IC package. An example sub-assembly may include a heterogenous package having one or more top dies coupled to a base die with a mold material surrounding the top dies. In another example, the one or more top dies may be coupled to an interposer or a substrate rather than a base die. A base die may include a silicon wafer. In some embodiments, an interposer may include an organic interposer, such as a dielectric material with conductive pathways therein (e.g., a redistribution layer (RDL)). In some embodiments, the one or more top dies may be coupled directly to a package substrate, overmolded, and then coupled to a circuit board. A first plurality of solder bump structures (e.g., solder bumps, balls, pads, pillar bumps (e.g., copper pillar bumps), etc.) of a generally uniform size can be positioned between the top die and the base die (or a substrate), and the top die and the base die may be heated to similar temperatures. The top die may then be lowered onto the base die, in order to mechanically and electrically couple the top die to the base die. Heat can be applied via a solder reflow process to re-melt the solder bumps and attach the top die to the base die forming die-to-die (DTD) interconnects, which may further be underfilled with a non-conductive adhesive to strengthen the mechanical connection between the top die and the base die. Manufacturing of an IC package can involve multiple thermal cycling (or processing) steps. For instance, a die may be heated to add solder balls (e.g., flip-chip or controlled collapse chip connection (C4) solder balls). The die may again be heated one or more times for placement and solder reflow. Another thermal cycle may be added if epoxy, for example, is used in the assembly process as an underfill material. An underfilling process, such as capillary flow underfilling, relies upon capillary pressure of the underfill material, to flow between the top die and the base die. More thermal cycles may be used to incorporate the subassembly into an IC package and to incorporate the IC package into an electronic assembly.

The multiple thermal cycles can lead to warpage of components of a resulting IC package or electronic assembly. Warpage refers to a bending or twist or general lack of flatness, particularly in the plane formed by solder joint locations. Such warpage is caused by a difference in CTE between one part or component and another. The problem of IC package warpage can be exacerbated in heterogenous packages due to a mismatch in footprint (e.g., surface area) between the base die and the top dies, which creates large areas of mold material. IC package warpage may also be exacerbated when soldering temperatures become higher and IC packages become thinner. Recently, the use of lead-free solders has become more prevalent on certain product types. This lead-free solder generally requires a higher soldering temperature than prior solders.

Warpage may pose a problem in forming solder joints, or interconnections, in IC packages. A lack of flatness may occur where the entire package warps so that it is curved or bent or otherwise non-flat. Lack of flatness in an IC package may cause various problems such as poor soldered joints between the components, poor or no contact at the solder joints, undesirably pillowed joints, intermittent contact at the solder joints, or solder bump bridging (SBB) (e.g., where multiple solder interconnects bond together). Such warpage may cause an IC package or an electronic assembly to fail. Package warpage is a significant challenge as it impacts the ability to handle the package during assembly steps. In addition, package warpage produces yield losses during reflow, which increases costs especially in heterogenous packages because multiple dies are discarded even if only a single die fails. As such, package warpage is therefore a major problem for package designs. Various ones of the embodiments disclosed herein may help achieve improved performance of IC packages, with reduced warpage, relative to conventional approaches.

Each of the structures, assemblies, packages, methods, devices, and systems of the present disclosure may have several innovative aspects, of which no single one is solely responsible for all the desirable attributes disclosed herein. Details of one or more implementations of the subject matter described in this specification are stated in the description below and the accompanying drawings.

In the following detailed description, various aspects of the illustrative implementations may be described using terms commonly employed by those skilled in the art to convey the substance of their work to others skilled in the art.

The terms “circuit” and “circuitry” mean one or more passive and/or active electrical and/or electronic components that are arranged to cooperate with one another to provide a desired function. The terms also refer to analog circuitry, digital circuitry, hard wired circuitry, programmable circuitry, microcontroller circuitry and/or any other type of physical hardware electrical and/or electronic component.

The term “integrated circuit” means a circuit that is integrated into a semiconductor or analogous material.

In some embodiments, the IC dies disclosed herein may comprise substantially monocrystalline semiconductors, such as silicon or germanium, as a base material on which integrated circuits are fabricated with traditional semiconductor processing methods. The semiconductor base material may include, for example, N-type or P-type materials. Dies may include, for example, a crystalline base material formed using a bulk silicon (or other bulk semiconductor material) or a semiconductor-on-insulator (SOI, e.g., a silicon-on-insulator) structure. In some other embodiments, the base material of one or more of the IC dies may comprise alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-N, group III-V, group II-VI, or group IV materials. In yet other embodiments, the base material may comprise compound semiconductors, for example, with a first sub-lattice of at least one element from group III of the periodic table (e.g., Al, Ga, In), and a second sub-lattice of at least one element of group V of the periodic table (e.g., P, As, Sb). In yet other embodiments, the base material may comprise an intrinsic IV or III-V semiconductor material or alloy, not intentionally doped with any electrically active impurity; in alternate embodiments, nominal impurity dopant levels may be present. In still other embodiments, dies may comprise a non-crystalline material, such as polymers; for example, the base material may comprise silica-filled epoxy. In other embodiments, the base material may comprise high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, the base material may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphide, and black phosphorus, each of which may possibly be doped with one or more of gallium, indium, aluminum, fluorine, boron, phosphorus, arsenic, nitrogen, tantalum, tungsten, and magnesium, etc. Although a few examples of the material for dies are described here, any material or structure that may serve as a foundation (e.g., base material) upon which IC circuits and structures as described herein may be built falls within the spirit and scope of the present disclosure.

Unless described otherwise, IC dies described herein include one or more IC structures (or, simply, “ICs”) implementing (i.e., configured to perform) certain functionality. In one such example, the term “memory die” may be used to describe a die that includes one or more ICs implementing memory circuitry (e.g., ICs implementing one or more of memory devices, memory arrays, control logic configured to control the memory devices and arrays, etc.). In another such example, the term “compute die” may be used to describe a die that includes one or more ICs implementing logic/compute circuitry (e.g., ICs implementing one or more of input/output (I/O) functions, arithmetic operations, pipelining of data, etc.).

In another example, the terms “package” and “IC package” are synonymous, as are the terms “die” and “IC die.” Note that the terms “chip,” “chiplet,” “die,” and “IC die” are used interchangeably herein.

The term “insulating” means “electrically insulating,” the term “conducting” means “electrically conducting,” unless otherwise specified. With reference to optical signals and/or devices, components and elements that operate on or using optical signals, the term “conducting” can also mean “optically conducting.”

The terms “oxide,” “carbide,” “nitride,” etc. refer to compounds containing, respectively, oxygen, carbon, nitrogen, etc.

The term “high-k dielectric” refers to a material having a higher dielectric constant than silicon oxide, while the term “low-k dielectric” refers to a material having a lower dielectric constant than silicon oxide.

The term “insulating material” refers to solid materials (and/or liquid materials that solidify after processing as described herein) that are substantially electrically nonconducting. They may include, as examples and not as limitations, organic polymers and plastics, and inorganic materials such as ionic crystals, porcelain, glass, silicon and alumina or a combination thereof. They may include dielectric materials, high polarizability materials, and/or piezoelectric materials. They may be transparent or opaque without departing from the scope of the present disclosure. Further examples of insulating materials are underfills and molds or mold-like materials used in packaging applications, including for example, materials used in organic interposers, package supports and other such components.

In various embodiments, elements associated with an IC may include, for example, transistors, diodes, power sources, resistors, capacitors, inductors, sensors, transceivers, receivers, antennas, etc. In various embodiments, elements associated with an IC may include those that are monolithically integrated within an IC, mounted on an IC, or those connected to an IC. The ICs described herein may be either analog or digital and may be used in a number of applications, such as microprocessors, optoelectronics, logic blocks, audio amplifiers, etc., depending on the components associated with the IC. The ICs described herein may be employed in a single IC die or as part of a chipset for executing one or more related functions in a computer.

In various embodiments of the present disclosure, transistors described herein may be field-effect transistors (FETs), e.g., metal oxide semiconductor (MOS) FETs (MOSFETs). In general, a FET is a three-terminal device that includes source, drain, and gate terminals and uses electric field to control current flowing through the device. A FET typically includes a channel material, a source region and a drain regions provided in and/or over the channel material, and a gate stack that includes a gate electrode material, alternatively referred to as a “work function” material, provided over a portion of the channel material (the “channel portion”) between the source and the drain regions, and optionally, also includes a gate dielectric material between the gate electrode material and the channel material.

In a general sense, an “interconnect” refers to any element that provides a physical connection between two other elements. For example, an electrical interconnect provides electrical connectivity between two electrical components, facilitating communication of electrical signals between them; an optical interconnect provides optical connectivity between two optical components, facilitating communication of optical signals between them. As used herein, both electrical interconnects and optical interconnects are comprised in the term “interconnect.” The nature of the interconnect being described is to be understood herein with reference to the signal medium associated therewith. Thus, when used with reference to an electronic device, such as an IC that operates using electrical signals, the term “interconnect” describes any element formed of an electrically conductive material for providing electrical connectivity to one or more elements associated with the IC or/and between various such elements. In such cases, the term “interconnect” may refer to both conductive traces (also sometimes referred to as “lines,” “wires,” or “metal lines”) and conductive vias (also sometimes referred to as “vias” or “metal vias”). Sometimes, electrically conductive traces and vias may be referred to as “conductive traces” and “conductive vias”, respectively, to highlight the fact that these elements include electrically conductive materials such as metals. Likewise, when used with reference to a device that operates on optical signals as well, such as a photonic IC (PIC), “interconnect” may also describe any element formed of a material that is optically conductive for providing optical connectivity to one or more elements associated with the PIC. In such cases, the term “interconnect” may refer to optical waveguides (e.g., structures that guide and confine light waves), including optical fiber, optical splitters, optical combiners, optical couplers, and optical vias.

The term “conductive trace” may be used to describe an electrically conductive element isolated by an insulating material. Within IC dies, such insulating material comprises interlayer low-k dielectric that is provided within the IC die. Within package substrates, and printed circuit boards (PCBs) such insulating material comprises organic materials such as Ajinomoto Buildup Film (ABF), polyimides, or epoxy resin. Such conductive lines are typically arranged in several levels, or several layers, of metallization stacks.

The term “conductive via” may be used to describe an electrically conductive element that interconnects two or more conductive lines of different levels of a metallization stack. To that end, a via may be provided substantially perpendicularly to the plane of an IC die/chip or a support structure over which an IC structure is provided and may interconnect two conductive lines in adjacent levels or two conductive lines in non-adjacent levels.

The term “package substrate” may be used to describe any substrate material that facilitates the packaging together of any collection of semiconductor dies and/or other electrical components such as passive electrical components. As used herein, a package substrate may be formed of any material including, but not limited to, insulating materials such as resin impregnated glass fibers (e.g., PCB or Printed Wiring Boards (PWB)), glass, ceramic, silicon, silicon carbide, etc. In addition, as used herein, a package substrate may refer to a substrate that includes buildup layers (e.g., ABF layers).

The term “metallization stack” may be used to refer to a stack of one or more interconnects for providing connectivity to different circuit components of an IC die/chip and/or a package substrate.

The terms “substantially,” “close,” “approximately,” “near,” and “about,” generally refer to being within +/−20% of a target value (e.g., within +/−5% or 10% of a target value) based on the context of a particular value as described herein or as known in the art.

Terms indicating orientation of various elements, e.g., “coplanar,” “perpendicular,” “orthogonal,” “parallel,” or any other angle between the elements, generally refer to being within +/−5%-20% of a target value based on the context of a particular value as described herein or as known in the art.

The term “connected” means a direct connection (which may be one or more of a mechanical, electrical, and/or thermal connection) between the things that are connected, without any intermediary devices, while the term “coupled” means either a direct connection between the things that are connected, or an indirect connection through one or more passive or active intermediary devices.

The description uses the phrases “in an embodiment” or “in embodiments,” which may each refer to one or more of the same or different embodiments.

Furthermore, the terms “comprising,” “including,” “having,” and the like, as used with respect to embodiments of the present disclosure, are synonymous.

The disclosure may use perspective-based descriptions such as “above,” “below,” “top,” “bottom,” and “side”; such descriptions are used to facilitate the discussion and are not intended to restrict the application of disclosed embodiments.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with one or both of the two layers or may have one or more intervening layers. In contrast, a first layer described to be “on” a second layer refers to a layer that is in direct contact with that second layer. Similarly, unless explicitly stated otherwise, one feature disposed between two features may be in direct contact with the adjacent features or may have one or more intervening layers.

The term “dispose” as used herein refers to position, location, placement, and/or arrangement rather than to any particular method of formation.

The term “between,” when used with reference to measurement ranges, is inclusive of the ends of the measurement ranges.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). When used herein, the notation “A/B/C” means (A), (B), and/or (C).

Although certain elements may be referred to in the singular herein, such elements may include multiple sub-elements. For example, “an electrically conductive material” may include one or more electrically conductive materials. In another example, “a dielectric material” may include one or more dielectric materials.

Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

In the following detailed description, reference is made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

The accompanying drawings are not necessarily drawn to scale.

In the drawings, same reference numerals refer to the same or analogous elements/materials shown so that, unless stated otherwise, explanations of an element/material with a given reference numeral provided in context of one of the drawings are applicable to other drawings where element/materials with the same reference numerals may be illustrated.

Furthermore, in the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using, e.g., images of suitable characterization tools such as scanning electron microscopy (SEM) images, transmission electron microscope (TEM) images, or non-contact profilometer. In such images of real structures, possible processing and/or surface defects could also be visible, e.g., surface roughness, curvature or profile deviation, pit or scratches, not-perfectly straight edges of materials, tapered vias or other openings, inadvertent rounding of corners or variations in thicknesses of different material layers, occasional screw, edge, or combination dislocations within the crystalline region(s), and/or occasional dislocation defects of single atoms or clusters of atoms. There may be other defects not listed here but that are common within the field of device fabrication and/or packaging.

Note that in the figures, various components (e.g., interconnects) are shown as aligned (e.g., at respective interfaces) merely for ease of illustration; in actuality, some or all of them may be misaligned. In addition, there may be other components, such as bond-pads, landing pads, metallization, etc. present in the assembly that are not shown in the figures to prevent cluttering. Further, the figures are intended to show relative arrangements of the components within their assemblies, and, in general, such assemblies may include other components that are not illustrated (e.g., various interfacial layers or various other components related to optical functionality, electrical connectivity, or thermal mitigation). For example, in some further embodiments, the assembly as shown in the figures may include more dies along with other electrical components. Additionally, although some components of the assemblies are illustrated in the figures as being planar rectangles or formed of rectangular solids, this is simply for ease of illustration, and embodiments of these assemblies may be curved, rounded, or otherwise irregularly shaped as dictated by and sometimes inevitable due to the manufacturing processes used to fabricate various components.

In the drawings, a particular number and arrangement of structures and components are presented for illustrative purposes and any desired number or arrangement of such structures and components may be present in various embodiments.

Further, unless otherwise specified, the structures shown in the figures may take any suitable form or shape according to material properties, fabrication processes, and operating conditions.

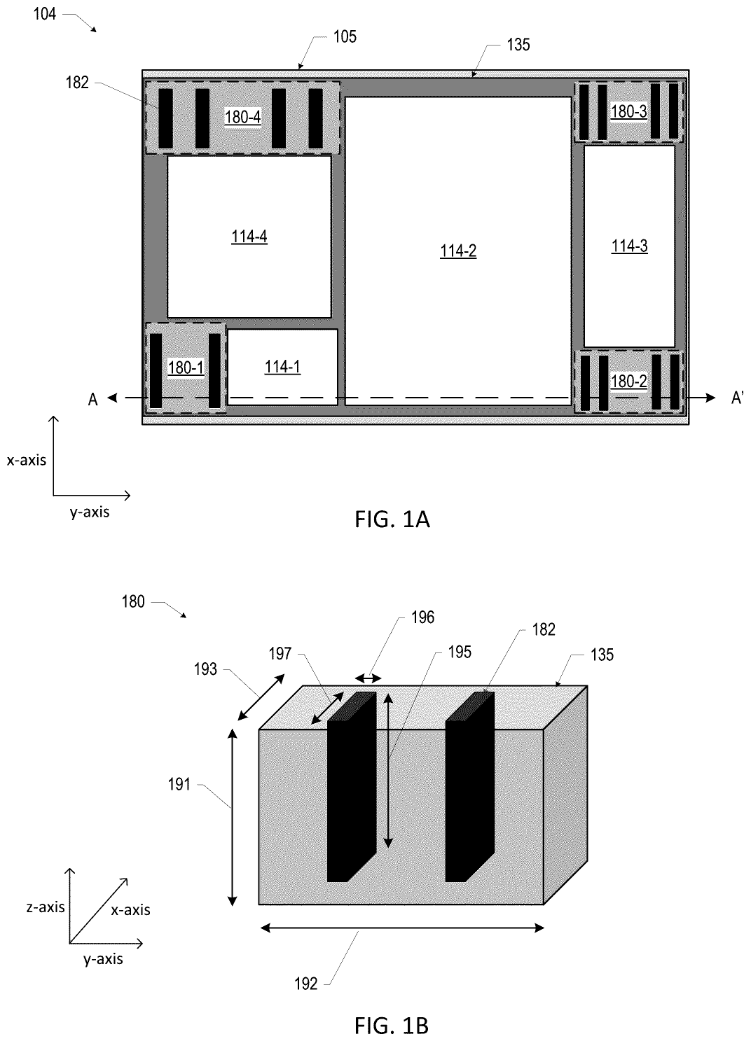

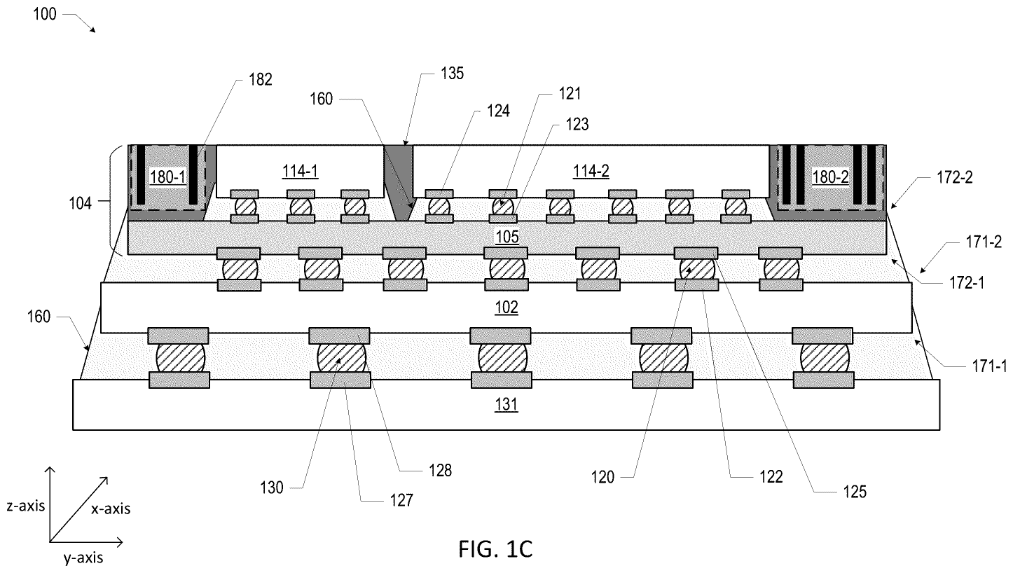

For convenience, if a collection of drawings designated with different letters are present (e.g., FIGS. 1A-1C), such a collection may be referred to herein without the letters (e.g., as “FIG. 1”). Similarly, if a collection of reference numerals designated with different numbers are present (e.g., 180-1, 180-2), such a collection may be referred to herein without the numbers (e.g., as “180”).

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

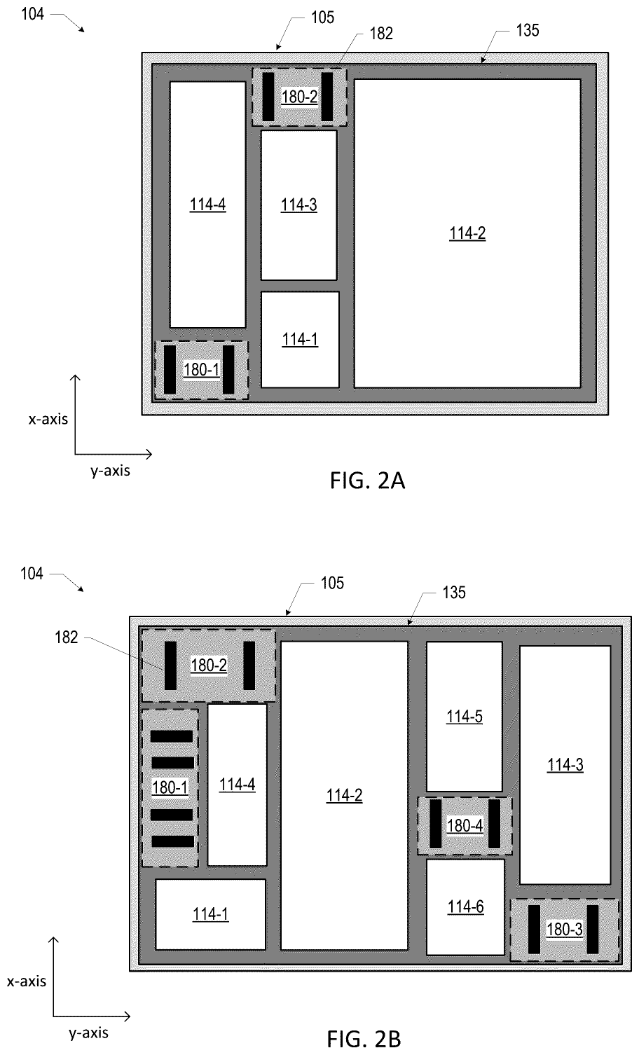

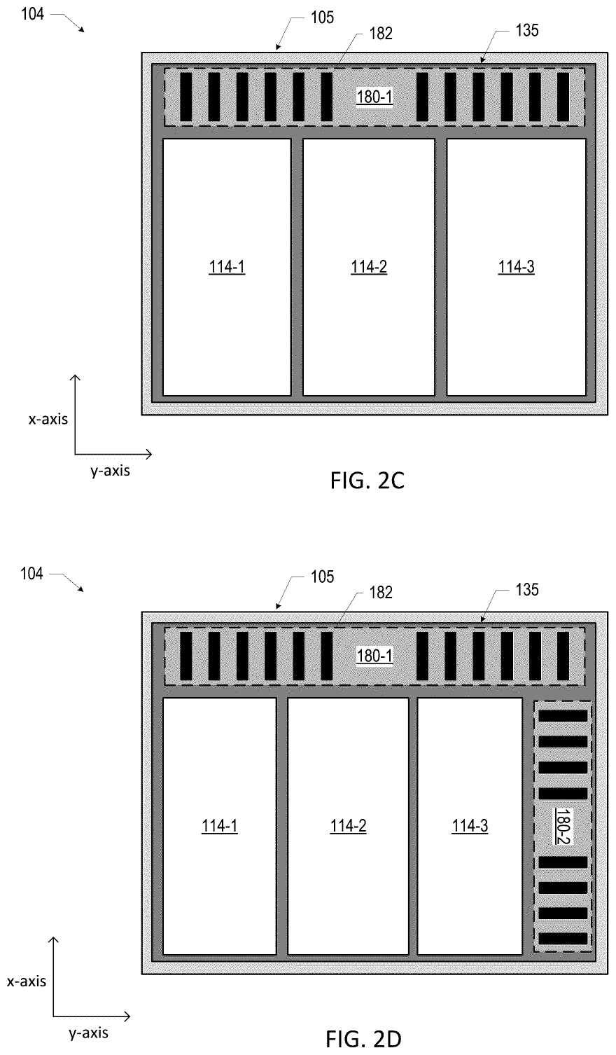

FIG. 1A is a top view of a microelectronic assembly 104, in accordance with various embodiments. A microelectronic assembly 104 also may be referred to herein as a “microelectronic sub-assembly.” The microelectronic assembly 104 may include a base die 105 with dies 114 (e.g., top dies 114-1, 114-2, 114-3, 114-4) disposed thereon and a mold material 135 surrounding the dies 114. The mold material 135 may further include a portion 180 (e.g., portions 180-1, 180-2, 180-3, 180-4) with a trench 182. The dies 114 may have different sizes and shapes (e.g., smaller footprints or surface areas) as compared to the base die 105 (e.g., a larger footprint) such that the dies 114 are surrounded by portions 180 of mold material that extend to cover the larger footprint of the base die 105. As used herein, a footprint or a surface area (e.g., of a die 114 or of a portion 180) refers to length (e.g., x-direction) times width (e.g., y-direction). Although FIG. 1A shows portions 180 at corners or along a perimeter (e.g., along outer edges) of a base die 105, portions 180 may be located in an inner part of the base die 105, as described below with reference to FIG. 2B. As used herein, a perimeter refers to an area adjacent to an outer edge of a component (e.g., of base die 105). Although FIG. 1A shows a mold material 135 having a smaller surface area as compared to a base die 105, in some embodiments, the mold material 135 has a same surface area as the base die 105, such that the mold material 135 completely covers the base die 105.

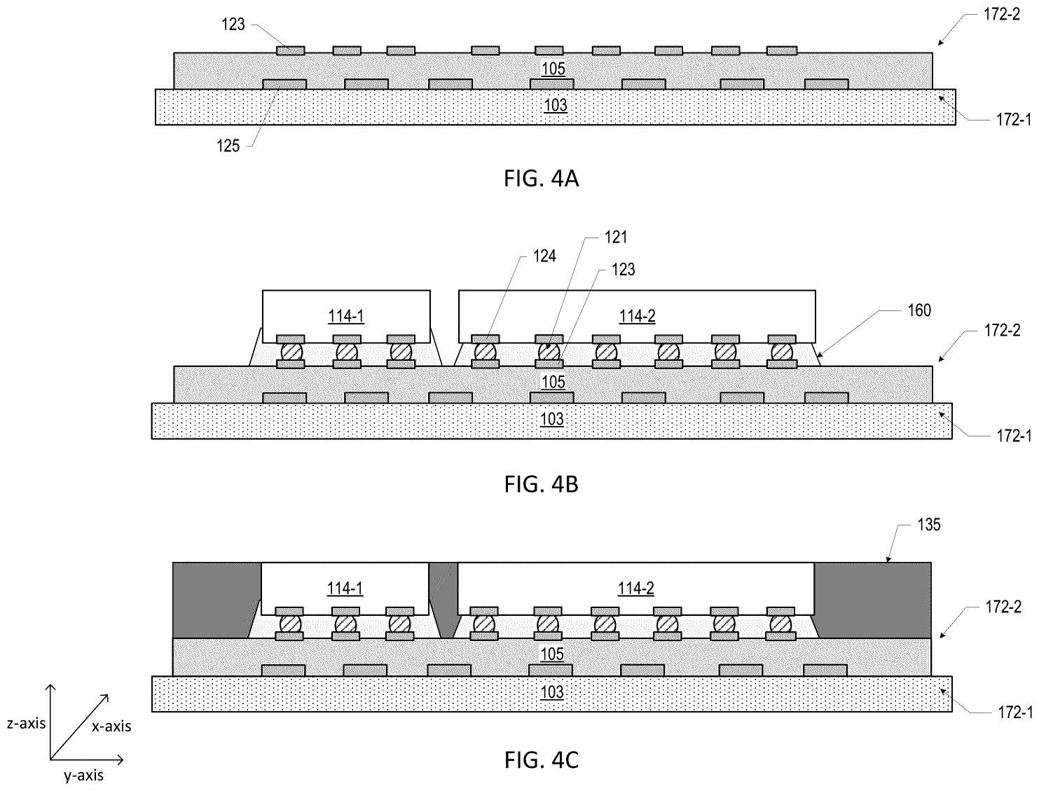

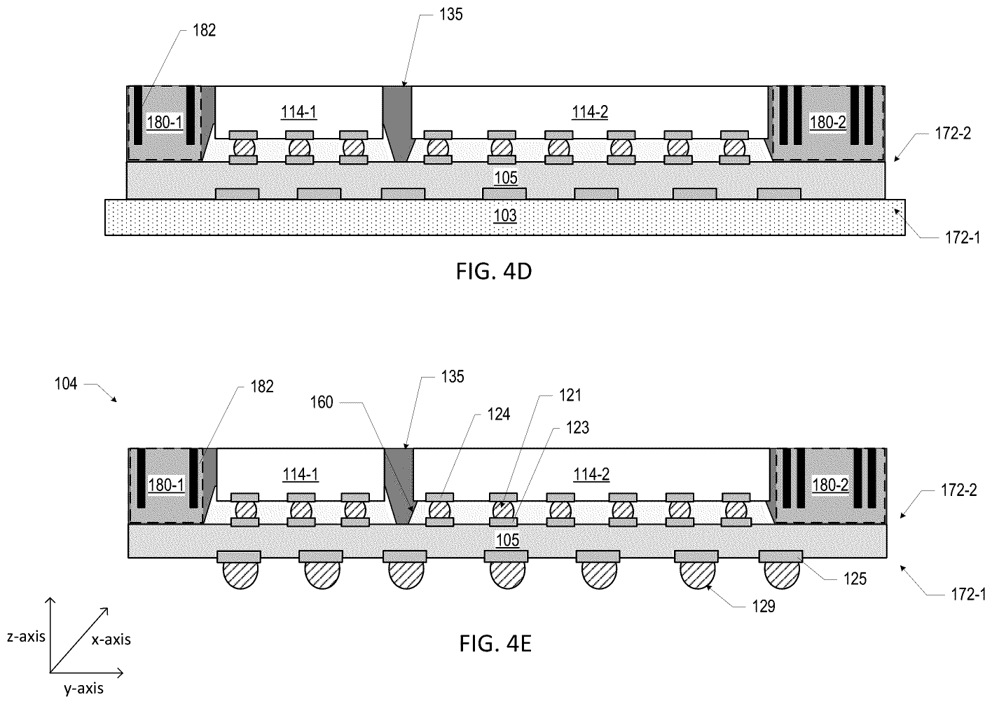

FIG. 1B is a more detailed, top view of a portion of the exemplary microelectronic assembly 104 of FIG. 1A, in accordance with various embodiments. As shown in FIG. 1B, a portion 180 of the mold material 135 may have a particular surface area that defines a mold shelf area. For example, a portion 180 may be identified as a mold shelf area when a portion 180 has a width 192 (e.g., a y-dimension) that is greater than or equal to 200 microns and a length 193 (e.g., x-dimension) that is greater than or equal to 200 microns. A thickness 191 (e.g., a z-height) of a mold material 135 may be determined by a thickness of the dies 114 or, if the dies 114 have different thickness, based on a thickness of the thickest die 114, for example, a thickness 191 may be between 50 microns and 800 microns. In some instances, a dummy silicon (not shown) may be disposed on the base die 105 to fill in areas around the dies 114, which decreases the amount of mold material 135 surrounding the dies 114 and reduces the CTE mismatch between the dies 114 and the mold material 135. If a portion 180 of the mold material 135 is too small, a dummy die may not be used. In such instances, the effects of the CTE mismatch between the dies 114 and the mold material 135 may be reduced by forming a trench 182 in a portion 180. For example, when the microelectronic assembly 104 is exposed to heat (e.g., during soldering), a mold material 135 may expand into the trench 182 to release stress and prevent warpage. Such a trench 182 may be formed by removing mold material 135 using any suitable technique, such as laser drilling or ablation, plasma, laser chemical etching, or combinations thereof. A trench 182 may have any suitable dimensions. As shown in FIG. 1B, the trench 182 may have a width 196 (e.g., y-direction), a length 197 (e.g., x-direction), and a height 195 (e.g., z-direction). For example, a trench 182 may have a width 196 between 50 microns and 300 microns, and the width 196 may depend on the technique used to form the trench 182. A trench 182 may have dimensions (e.g., a width 196, a length 197, and a height 195) that are less than the dimensions of a portion 180 (e.g., a width 192, a length 193, and a thickness 191), such that the trench 182 does not extend to a side edge or a bottom edge of the mold material 135 (e.g., a trench 182 is positioned at least 50 microns from any outside edge of the mold material 135 or from any outside edge of a top die 114, and at least 5 to 10 microns from a bottom edge of the mold material 135). Although the trench 182 is shown to have straight (e.g., perpendicular) walls, the trench 182 may have slanted or angled walls. Further, although the trenches 182 in a portion 180 are shown to have same dimensions, the trenches 182 may have different dimensions. A portion 180 may include any suitable number of trenches 182, including one or more, and any suitable arrangement, as described below with reference to FIG. 4. A number and arrangement of trenches 182 may configured to optimize stress release of the mold material 135 under thermal cycles while maintaining structural support, for example, an overall volume of a trench may be limited to a percent of an overall volume of the portion 180 of the mold material. In such embodiments, a total volume of a trench 182 (e.g., a total volume of a plurality of trenches) is equal to between 10 percent and 50 percent of a total volume of the portion 180 of the mold material 135. In some embodiments, a trench 182 may be an opening that contains air. In some embodiments, a trench 182 may be filled with a material, other than air, for example, a capillary underfill material (e.g., a curable resin material with or without fillers), a self-healing polymer (e.g., a hydrogel), a porous dielectric (e.g., a polyethylene), an elastomer (e.g., a natural rubber or a polyurethane), or other similar materials, which may be more pliable than the mold material 135 and may assist with relieving stresses to the mold material 135 under thermal cycles. The material may be deposited in a trench 182 using any suitable technique, which may depend on the material being deposited in the trench 182, such as a capillary underfill process or a Plasma Enhanced Chemical Vapor Deposition (PECVD) process.

FIG. 1C is a side, cross-sectional view of an exemplary microelectronic assembly along the A-A′ line of FIG. 1A, in accordance with various embodiments. As shown in FIG. 1C, a microelectronic assembly 104 may be incorporated into a microelectronic assembly 100. A microelectronic assembly 104 may include top dies 114 disposed on a base die 105 and surrounded by a mold material 135. In particular, a base die 105 may include a first surface 172-1 (e.g., a bottom surface) having conductive contacts 125 and an opposing second surface 172-2 (e.g., a top surface) having conductive contacts 123. Conductive contacts 124 on a surface of dies 114 (e.g., die 114-1, 114-2) may be electrically coupled to conductive contacts 123 on the second surface 172-2 of the base die 105 by interconnects 121. The interconnects 121 may be surrounded by an underfill material 160 (e.g., the underfill material 160 may be disposed between the die 114 and the second surface 172-2 of the base die 105). A mold material 135 may be on the second surface 172-2 of the base die 105 and around the dies 114 and interconnects 121. The mold material 135 may include portions 180 (e.g., portions 180-1, 180-2) of excessive mold shelf areas having trenches 182.

The mold material 135 may include any suitable insulating material that provides mechanical support to the microelectronic component 104. In some embodiments, the mold material 135 is an organic polymer. In some embodiments, the mold material 135 is an organic polymer with a filler, such as inorganic silica particles or alumina. In some embodiments, the mold material 135 is an organic dielectric material, a fire retardant grade 4 material (FR-4), a bismaleimide triazine (BT) resin, a polyimide material, a glass reinforced epoxy matrix material, or a low-k and ultra-low-k dielectric (e.g., carbon-doped dielectrics, fluorine-doped dielectrics, porous dielectrics, and organic polymeric dielectrics). In some embodiments, the mold material 135 is an epoxy mold compound, an epoxy-based dielectric, or a photo-imageable dielectric.

The microelectronic assembly 100 may further include a substrate 102. The substrate 102 may include a first surface 171-1 (e.g., a bottom surface) having conductive contacts 128 and an opposing second surface 171-2 (e.g., a top surface) having conductive contacts 122. Conductive contacts 125 on the first surface 172-1 of the base die 105 may be electrically coupled to conductive contacts 122 on the second surface of the substrate by interconnects 120. The interconnects 120 may be surrounded by an underfill material 160 (e.g., the underfill material 160 may be disposed between the first surface 172-1 of the base die 105 and the second surface 171-2 of the substrate 102).

In some embodiments, the interconnects 120, 121 may include solder bumps or balls (as illustrated in FIG. 1C); in other embodiments, the interconnects 120, 121, 126 may include copper pillars, metal-to-metal interconnects, or any other suitable interconnects surrounded by an underfill material 160. In some embodiments, the interconnects 120, 121, 126 may include an anisotropic conductive material, such as an anisotropic conductive film or an anisotropic conductive paste. An anisotropic conductive material may include conductive materials dispersed in a non-conductive material.

The underfill material 160 may be any suitable material. The underfill material 160 may be an insulating material, such as an appropriate epoxy material. In some embodiments, the underfill material 160 may include a capillary underfill, non-conductive film (NCF), or molded underfill. The underfill material 160 may be selected to have a CTE that may mitigate or minimize the stress between the die 114 and the base die 105, and the base die 105 and the substrate 102. In some embodiments, the underfill material 160 may include an epoxy flux that assists with soldering the die 114 to the base die 105, and the base die 105 to the substrate 102, when forming the interconnects 120, 121, respectively, and then polymerizes and encapsulates the interconnects 120, 121. In some embodiments, the CTE of the underfill material 160 may have a value that is intermediate to the CTE of the die 114, the base die 105, and the substrate 102 (e.g., the CTE of the dielectric material of the substrate 102).

The die 114 disclosed herein may include an insulating material (e.g., a dielectric material formed in multiple layers, as known in the art) and multiple conductive pathways formed through the insulating material. In some embodiments, the insulating material of a die 114 may include a dielectric material, such as silicon dioxide, silicon nitride, oxynitride, polyimide materials, glass reinforced epoxy matrix materials, or a low-k or ultra low-k dielectric (e.g., carbon-doped dielectrics, fluorine-doped dielectrics, porous dielectrics, organic polymeric dielectrics, photo-imageable dielectrics, and/or benzocyclobutene-based polymers). In some embodiments, the insulating material of a die 114 may include a semiconductor material, such as silicon, germanium, or a III-V material (e.g., gallium nitride), and one or more additional materials. For example, an insulating material may include silicon oxide or silicon nitride. The conductive pathways in a die 114 may include conductive traces and/or conductive vias, and may connect any of the conductive contacts in the die 114 in any suitable manner (e.g., connecting multiple conductive contacts on a same surface or on different surfaces of the die 114). Example structures that may be included in the dies 114 disclosed herein are discussed below with reference to FIG. 7. The conductive pathways in the dies 114 may be bordered by liner materials, such as adhesion liners and/or barrier liners, as suitable. The dies 114 may perform any suitable functionality, and may include processing devices, memory, communications devices, sensors, or any other computing components or circuitry. For example, the dies may include a central processing unit (CPU), a platform controller hub (PCH), a dynamic random access memory (DRAM), a graphic processing unit (GPU), and a field programmable gate array (FPGA). A base die 105 may include the same materials and structures as the dies 114.

The substrate 102 may include an insulating material (e.g., a dielectric material formed in multiple layers, as known in the art) and one or more conductive pathways (not shown) to route power, ground, and signals through the dielectric material (e.g., including conductive traces and/or conductive vias, as shown). In some embodiments, the insulating material of the substrate 102 may be a dielectric material, such as an organic dielectric material, a fire retardant grade 4 material (FR-4), bismaleimide triazine (BT) resin, polyimide materials, glass reinforced epoxy matrix materials, organic dielectrics with inorganic fillers or low-k and ultra low-k dielectric (e.g., carbon-doped dielectrics, fluorine-doped dielectrics, porous dielectrics, and organic polymeric dielectrics). In particular, when the substrate 102 is formed using standard PCB processes, the substrate 102 may include FR-4, and the conductive pathways in the substrate 102 may be formed by patterned sheets of copper separated by build-up layers of the FR-4. The conductive pathways in the substrate 102 may be bordered by liner materials, such as adhesion liners and/or barrier liners, as suitable. In some embodiments, the substrate 102 may be a coreless substrate, a UTC substrate, a wafer level packaging, or any other suitable package designed to minimize z-height, as is known in the art. The substrate 102 may include conductive pathways (not shown) that allow power, ground, and other electrical signals to move between the microelectronic assembly 104 and the substrate 102. In some embodiments, the microelectronic assembly 104 may not be coupled to a substrate 102, but may instead be coupled to an interposer, a package substrate, or a circuit board, such as a PCB.

In some embodiments, the substrate 102 may be formed using a lithographically defined via packaging process. In some embodiments, the substrate 102 may be manufactured using standard organic package manufacturing processes, and thus the substrate 102 may take the form of an organic package. In some embodiments, the substrate 102 may be a set of redistribution layers formed on a panel carrier by laminating or spinning on a dielectric material, and creating conductive vias and lines by laser drilling or ablation and plating. In some embodiments, the substrate 102 may be formed on a removable carrier using any suitable technique, such as a redistribution layer technique. Any method known in the art for fabrication of the substrate 102 may be used, and for the sake of brevity, such methods will not be discussed in further detail herein.

In some embodiments, the substrate 102 may be a lower density medium and the base die 105 may be a higher density medium or have an area with a higher density medium. As used herein, the term “lower density” and “higher density” are relative terms indicating that the conductive pathways (e.g., including conductive interconnects, conductive lines, and conductive vias) in a lower density medium are larger and/or have a greater pitch than the conductive pathways in a higher density medium. In some embodiments, a higher density medium may be manufactured using a modified semi-additive process or a semi-additive build-up process with advanced lithography (with small vertical interconnect features formed by advanced laser or lithography processes), while a lower density medium may be a PCB manufactured using a standard PCB process (e.g., a standard subtractive process using etch chemistry to remove areas of unwanted copper, and with coarse vertical interconnect features formed by a standard laser process). In other embodiments, the higher density medium may be manufactured using semiconductor fabrication process, such as a single damascene process or a dual damascene process.

The microelectronic assembly 100 may further include a circuit board 131. The circuit board 131 may include conductive contacts 127 on a surface. Conductive contacts 128 on the first surface 171-1 of the substrate 102 may be electrically coupled to conductive contacts 127 on the circuit board 131 by interconnects 126. In some embodiments, the interconnects 126 may include solder balls (as illustrated in FIG. 1C) for a ball grid array (BGA) coupling; in other embodiments, the interconnects 126 may include solder paste contacts to provide land grid array (LGA) interconnects, or any other suitable interconnect. The interconnects 126 may be surrounded by an underfill material 160 (e.g., the underfill material 160 may be disposed between the first surface 171-1 of the substrate 102 and the surface of the circuit board 131). In some embodiments, the circuit board 131 may include one or more components disposed thereon (not shown). The circuit board 131 may include conductive pathways that allow power, ground, and other electrical signals to move between the circuit board 131 and the substrate 102 as well as between the circuit board 131 and the microelectronic assembly 104, as known in the art.

Although FIG. 1 illustrates a single microelectronic assembly 104 (e.g., base die 105 with die 114) disposed on a substrate 102, this is simply for ease of illustration and multiple microelectronic assemblies 104 with may be disposed on the substrate 102 and multiple substrates 102 may be disposed on a circuit board 131. In some embodiments, the circuit board 131 may be a PCB (e.g., a motherboard). In some embodiments, the circuit board 131 may be another IC package, and the microelectronic assembly 100 may be a package-on-package structure. In some embodiments, the circuit board 131 may be an interposer, and the microelectronic assembly 100 may be a package-on-interposer structure.

Many of the elements of the microelectronic assembly 100 of FIG. 1 are included in other ones of the accompanying figures; the discussion of these elements is not repeated when discussing these figures, and any of these elements may take any of the forms disclosed herein. Some of the elements of the microelectronic assembly 100 of FIG. 1 are not included in other ones of the accompanying figures for simplicity, but a microelectronic assembly 100 may include these omitted elements. In some embodiments, individual ones of the microelectronic assemblies 104 disclosed herein may serve as a system-in-package (SiP) in which multiple dies 114 having different functionality are included. In such embodiments, the microelectronic assembly 104 may be referred to as an SiP.

FIG. 2A is a top view of another microelectronic assembly 104, in accordance with various embodiments. The microelectronic assembly 104 may include a base die 105 with dies 114 (e.g., top dies 114-1, 114-2, 114-3, 114-4) disposed thereon and a mold material 135 surrounding the dies 114. The mold material 135 may further include a portion 180 (e.g., portions 180-1, 180-2) with a trench 182. The portion 180-1 may be located at corner and the portion 180-2 may be located along a perimeter (e.g., along an outer edge) of the base die 105.

FIG. 2B is a top view of yet another microelectronic assembly 104, in accordance with various embodiments. The microelectronic assembly 104 may include a base die 105 with dies 114 (e.g., top dies 114-1, 114-2, 114-3, 114-4, 114-5, 114-6) disposed thereon and a mold material 135 surrounding the dies 114. The mold material 135 may further include a portion 180 (e.g., portions 180-1, 180-2, 180-3, 180-4) with a trench 182. The portion 180-1 may be located along a perimeter, the portions 180-2, 180-3 may be located at different corners, and the portion 180-4 may be located in an inner part of the base die 105 (e.g., surrounded by dies 114-2, 114-3, 114-5, 114-6).

FIG. 2C is a top view of another microelectronic assembly 104, in accordance with various embodiments. The microelectronic assembly 104 may include a base die 105 with dies 114 (e.g., top dies 114-1, 114-2, 114-3) disposed thereon and a mold material 135 surrounding the dies 114. The mold material 135 may further include a portion 180 (e.g., portion 180-1) with a trench 182. The portion 180-1 may be located along an outside edge of the base die 105.

FIG. 2D is a top view of another microelectronic assembly 104, in accordance with various embodiments. The microelectronic assembly 104 may include a base die 105 with dies 114 (e.g., top dies 114-1, 114-2, 114-3) disposed thereon and a mold material 135 surrounding the dies 114. The mold material 135 may further include a portion 180 (e.g., portions 180-1, 180-2) with a trench 182. The portion 180-1 may be located along a first outside edge of the base die 105 and the portion 180-2 may be located along a second outside edge of the base die 105. Although FIGS. 1A and 2A-2D illustrate a particular number and arrangement dies 114 and portions 180 of mold material 135, these are simply illustrative, and a microelectronic assembly 104 may have any suitable number and arrangement of dies 115 and portions 180.

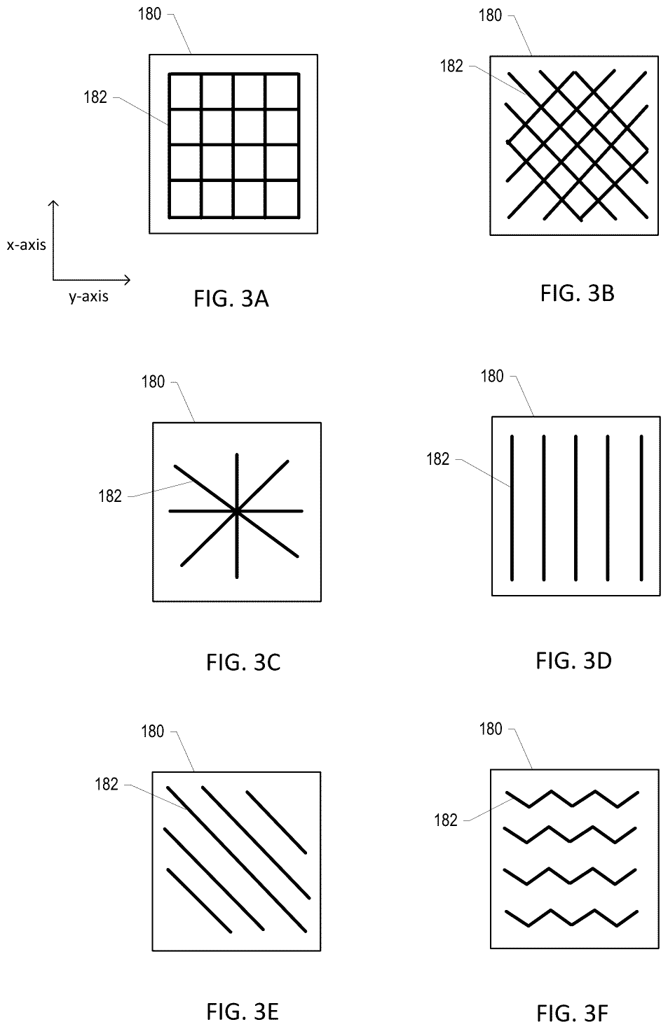

FIGS. 3A-3F are top views of exemplary trench arrangements in microelectronic assemblies, in accordance with various embodiments. FIGS. 3A, 3B, and 3C show example arrangements of intersecting trenches 182 in a portion 180, and FIGS. 3D, 3E, and 3F show example arrangements of non-intersecting trenches 182 in a portion 180. FIG. 3A shows a plurality of trenches 182 arranged in a rectangular grid pattern. FIG. 3B shows a plurality of trenches 182 arranged in a diamond grid pattern. In some embodiments, the diamond grid pattern may have trenches at a top, a bottom, and both sides (not shown) similar to the rectangular grid pattern in FIG. 3A. FIG. 3C shows an asterisk or star pattern where a plurality of trenches 182 intersect at a midpoint. FIG. 3D shows a plurality of trenches 182 aligned parallel to each other. The trenches 182 may be aligned vertically, as shown, or may be aligned horizontally. FIG. 3E shows a plurality of trenches 182 aligned diagonally and parallel to each other. FIG. 3F shows a plurality of trenches 182 having a zigzag pattern aligned parallel to each other. The trenches 182 may be aligned horizontally, as shown, or may be aligned vertically. Although FIGS. 3A-3F illustrate a particular number and arrangement trenches 182 in a portion 180 of mold material 135, these are simply illustrative, and a microelectronic assembly 104 may have any suitable number and arrangement of trenches 182 in a portion 180 of mold material 135.

Any suitable techniques may be used to manufacture the microelectronic assemblies 104 disclosed herein. For example, FIGS. 4A-4E are side, cross-sectional views of various stages in an example process for manufacturing the microelectronic assembly 104 of FIG. 1C, in accordance with various embodiments. Although the operations discussed below with reference to FIGS. 4A-4E are illustrated in a particular order, these operations may be performed in any suitable order. Further, additional operations which are not illustrated may also be performed without departing from the scope of the present disclosure. Also, various ones of the operations discussed herein with respect to FIGS. 4A-4E may be modified in accordance with the present disclosure to fabricate others of microelectronic assembly 104 disclosed herein.

FIG. 4A illustrates an assembly subsequent to mounting a first surface 172-1 of a base die 105 to a carrier 103. The first surface 172-1 of the base die 105 may include conductive contacts 125 and the second surface 172-2 of the base die 105 may include conductive contacts 123. A carrier 103 may include any suitable material for providing mechanical stability during manufacturing operations, and in some embodiments, may include a semiconductor wafer (e.g., a silicon wafer) or glass (e.g., a glass panel). In some embodiments, the base die 105 may act as a carrier and, in such instances, the carrier 103 may be omitted.

FIG. 4B illustrates an assembly subsequent to placing dies 114-1, 114-2 on the second surface 172-2 of the base die 105, forming interconnects 121, and depositing an underfill 160 around the interconnects 121. Any suitable method may be used to place the dies 114-1, 114-2, for example, automated pick-and-place. The dies 114-1, 114-2 may include a set of conductive contacts 124 on a bottom surface. In some embodiments, the interconnects 121 may include solder. In such embodiments, the assembly of FIG. 4B may be subjected to a solder reflow process during which solder components of the interconnects 121 melt and bond to mechanically and electrically couple the dies 114-1, 114-2 to the top surface of the assembly of FIG. 4A. The underfill 160 may be deposited using any suitable technique, such as capillary underfill. In some embodiments, the underfill 160 may be omitted.

FIG. 4C illustrates an assembly subsequent to depositing a mold material 135 on the second surface 172-2 of the base die 105 and on and around the die 114-1, 114-2. The mold material 135 may include any suitable mold material including, as described above with reference to FIG. 1. The mold material 135 may be formed using any suitable process, including, for example, transfer molding, compression molding, lamination, or slit coating and curing. In some embodiments, the mold material 135 may be dispensed in liquid form to flow around and conform to various shapes of components and metallization, and, subsequently, may be subjected to a process, for example, curing, that solidifies the mold material 135. In some embodiments, the mold material 135 may be initially deposited on and over the top surface of the die 114-1, 114-2, then polished back to expose the top surface of the die 114-1, 114-2. If the mold material 135 is formed to completely cover the die 114-1, 114-2, the mold material 135 may be removed using any suitable technique, including grinding, or etching, such as a dry etch (e.g., a plasma etch), a wet blast, or a laser ablation (e.g., using excimer laser). In some embodiments, the thickness of the mold material 135 may be minimized to reduce the etching time required. In some embodiments, the top surface of the mold material 135 may be planarized using any suitable process, such as chemical mechanical polishing (CMP).

FIG. 4D illustrates an assembly subsequent to identifying a portion 180 (e.g., portion 180-1, 180-2) of the mold material 135 that is an excessive mold shelf area, as described above with reference to FIG. 1, and forming a trench 182. The trench 182, which is an opening in the mold material 135 where the mold material 135 has been removed, may be formed and patterned using any suitable technique, such as laser drilling or laser ablation (e.g., using excimer laser). The trench 182, in terms of size, shape, number, and arrangement, may be patterned to optimally reduce warpage due to CTE mismatch between the mold material 135 and the dies 114 and the base die 105.

FIG. 4E illustrates an assembly subsequent to removing the carrier 103 and performing finishing operations on a bottom surface of the assembly of FIG. 4D, such as depositing a passivation material (e.g., silicon nitride) (not shown) and plating solder 129 on conductive contacts 125 at a bottom surface 172-1 of the base die 105. In some embodiments, conductive contacts 125 on the bottom surface 172-1 of the base die 105 may be formed subsequent to removing the carrier 103. If multiple assemblies are manufactured together, the assemblies may be singulated after removal of the carrier 103. The assembly of FIG. 4E may itself be a microelectronic assembly 104, as shown. Further manufacturing operations may be performed on the microelectronic assembly 104 of FIG. 4E to form other microelectronic assembly 100; for example, the solder 129 may be used to couple the microelectronic assembly 104 of FIG. 4E to a substrate 102 via interconnects 120, and, optionally, the substrate 102 to a circuit board 131 by interconnects 130, similar to the microelectronic assembly 100 of FIG. 1C.

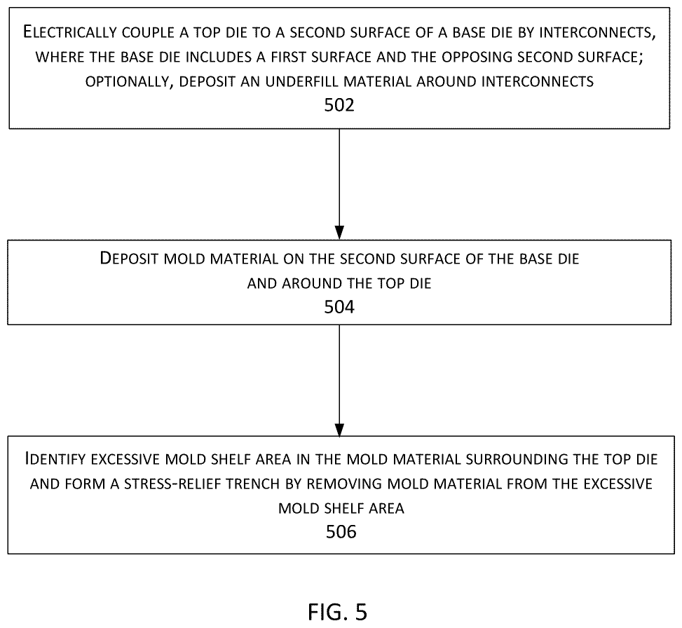

FIG. 5 is a flow diagram of an example method of manufacturing a microelectronic assembly, in accordance with various embodiments. At 502, a die 114 may be electrically coupled to a top surface (e.g., a second surface 172-2) of a base die 105 by forming interconnects 121. Any suitable method may be used to place the die 114, for example, automated pick-and-place. In some embodiments, the interconnects 121 may include solder. In such embodiments, the assembly may be subjected to a solder reflow process during which solder components of the interconnects 121 melt and bond to mechanically and electrically couple the die 114 to the top surface 172-2 of the base die 105. In some embodiments, an underfill material 160 may be deposited around the interconnects 121. The underfill material 160 may include any suitable material, including as described above with reference to FIG. 1, and may be dispensed using any suitable process, including capillary underfill or molded underfill and subsequently cured. At 504, a mold material 135 may be deposited on a top surface 172-2 of the base die 105 and on and around the die 114. If the mold material 135 is deposited over the die 114, the mold material 135 may be planarized using any suitable technique, such as grinding. At 506, a portion 180 of the mold material 135 may be identified as an excessive mold shelf area and a trench 182 may be formed in the portion 180. The trench 182 may be formed by removing mold material 135 from the portion 180. The size, shape, number, and arrangement of the trench 182 may be determined based on a desired counterbalance for warpage experienced by the microelectronic assembly 104 without the trench 182. Further operations may be performed, such as electrically coupling the bottom surface 172-1 of the base die 105 to a substrate 102.

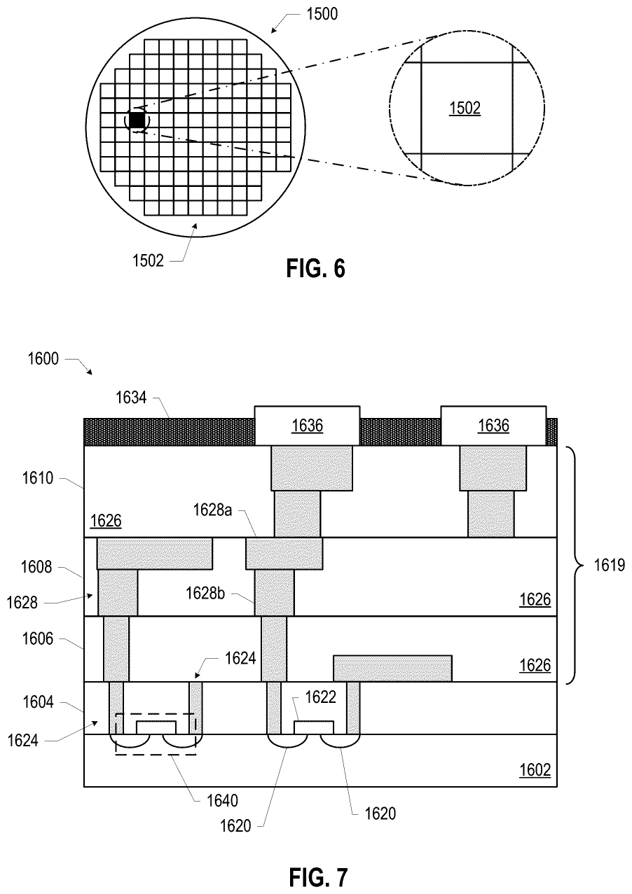

The microelectronic assemblies 100 (e.g., including microelectronic assemblies 104) disclosed herein may be included in any suitable electronic component. FIGS. 6-9 illustrate various examples of apparatuses that may include, or be included in, any of the microelectronic assemblies 100, 104 disclosed herein.

FIG. 6 is a top view of a wafer 1500 and dies 1502 that may be included in any of the microelectronic assemblies 100 disclosed herein (e.g., as any suitable ones of the dies 114 and/or the base die 105). The wafer 1500 may be composed of semiconductor material and may include one or more dies 1502 having IC structures formed on a surface of the wafer 1500. Each of the dies 1502 may be a repeating unit of a semiconductor product that includes any suitable IC. After the fabrication of the semiconductor product is complete, the wafer 1500 may undergo a singulation process in which the dies 1502 are separated from one another to provide discrete “chips” of the semiconductor product. The die 1502 may be any of the dies 114 disclosed herein. The die 1502 may include one or more transistors (e.g., some of the transistors 1640 of FIG. 7, discussed below), supporting circuitry to route electrical signals to the transistors, passive components (e.g., signal traces, resistors, capacitors, or inductors), and/or any other IC components. In some embodiments, the wafer 1500 or the die 1502 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 9) or other logic that is configured to store information in the memory devices or execute instructions stored in the memory array. In some embodiments, a die 1502 (e.g., a die 114) may be a central processing unit, a radio frequency chip, a power converter, or a network processor. Various ones of the microelectronic assemblies 100 disclosed herein may be manufactured using a die-to-wafer assembly technique in which some dies 114 are attached to a wafer 1500 that include the base dies 105, and the wafer 1500 is subsequently singulated.

FIG. 7 is a cross-sectional side view of an IC device 1600 that may be included in any of the microelectronic assemblies 100 disclosed herein (e.g., in any of the dies 114). One or more of the IC devices 1600 may be included in one or more dies 1502 (FIG. 6). The IC device 1600 may be formed on a die substrate 1602 (e.g., the wafer 1500 of FIG. 6) and may be included in a die (e.g., the die 1502 of FIG. 6). The die substrate 1602 may be a semiconductor substrate composed of semiconductor material systems including, for example, n-type or p-type materials systems (or a combination of both). The die substrate 1602 may include, for example, a crystalline substrate formed using a bulk silicon or a silicon-on-insulator (SOI) substructure. In some embodiments, the die substrate 1602 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1602. Although a few examples of materials from which the die substrate 1602 may be formed are described here, any material that may serve as a foundation for an IC device 1600 may be used. The die substrate 1602 may be part of a singulated die (e.g., the dies 1502 of FIG. 6) or a wafer (e.g., the wafer 1500 of FIG. 6).

The IC device 1600 may include one or more device layers 1604 disposed on the die substrate 1602. The device layer 1604 may include features of one or more transistors 1640 (e.g., metal oxide semiconductor field-effect transistors (MOSFETs)) formed on the die substrate 1602. The device layer 1604 may include, for example, one or more source and/or drain (S/D) regions 1620, a gate 1622 to control current flow in the transistors 1640 between the S/D regions 1620, and one or more S/D contacts 1624 to route electrical signals to/from the S/D regions 1620. The transistors 1640 may include additional features not depicted for the sake of clarity, such as device isolation regions, gate contacts, and the like. The transistors 1640 are not limited to the type and configuration depicted in FIG. 7 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 1640 may include a gate 1622 formed of at least two layers, a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1640 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer. For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1640 along the source-channel-drain direction, the gate electrode may consist of a U-shaped structure that includes a bottom portion substantially parallel to the surface of the die substrate 1602 and two sidewall portions that are substantially perpendicular to the top surface of the die substrate 1602. In other embodiments, at least one of the metal layers that form the gate electrode may simply be a planar layer that is substantially parallel to the top surface of the die substrate 1602 and does not include sidewall portions substantially perpendicular to the top surface of the die substrate 1602. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1620 may be formed within the die substrate 1602 adjacent to the gate 1622 of each transistor 1640. The S/D regions 1620 may be formed using an implantation/diffusion process or an etching/deposition process, for example. In the former process, dopants such as boron, aluminum, antimony, phosphorous, or arsenic may be ion-implanted into the die substrate 1602 to form the S/D regions 1620. An annealing process that activates the dopants and causes them to diffuse farther into the die substrate 1602 may follow the ion-implantation process. In the latter process, the die substrate 1602 may first be etched to form recesses at the locations of the S/D regions 1620. An epitaxial deposition process may then be carried out to fill the recesses with material that is used to fabricate the S/D regions 1620. In some implementations, the S/D regions 1620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1620 may be formed using one or more alternate semiconductor materials such as germanium or a group III-V material or alloy. In further embodiments, one or more layers of metal and/or metal alloys may be used to form the S/D regions 1620.

Electrical signals, such as power and/or input/output (I/O) signals, may be routed to and/or from the devices (e.g., transistors 1640) of the device layer 1604 through one or more interconnect layers disposed on the device layer 1604 (illustrated in FIG. 7 as interconnect layers 1606-1610). For example, electrically conductive features of the device layer 1604 (e.g., the gate 1622 and the S/D contacts 1624) may be electrically coupled with the interconnect structures 1628 of the interconnect layers 1606-1610. The one or more interconnect layers 1606-1610 may form a metallization stack (also referred to as an “ILD stack”) 1619 of the IC device 1600.

The interconnect structures 1628 may be arranged within the interconnect layers 1606-1610 to route electrical signals according to a wide variety of designs; in particular, the arrangement is not limited to the particular configuration of interconnect structures 1628 depicted in FIG. 7. Although a particular number of interconnect layers 1606-1610 is depicted in FIG. 7, embodiments of the present disclosure include IC devices having more or fewer interconnect layers than depicted.

In some embodiments, the interconnect structures 1628 may include lines 1628a and/or vias 1628b filled with an electrically conductive material such as a metal. The lines 1628a may be arranged to route electrical signals in a direction of a plane that is substantially parallel with a surface of the die substrate 1602 upon which the device layer 1604 is formed. For example, the lines 1628a may route electrical signals in a direction in and out of the page from the perspective of FIG. 7. The vias 1628b may be arranged to route electrical signals in a direction of a plane that is substantially perpendicular to the surface of the die substrate 1602 upon which the device layer 1604 is formed. In some embodiments, the vias 1628b may electrically couple lines 1628a of different interconnect layers 1606-1610 together.

The interconnect layers 1606-1610 may include a dielectric material 1626 disposed between the interconnect structures 1628, as shown in FIG. 7. In some embodiments, the dielectric material 1626 disposed between the interconnect structures 1628 in different ones of the interconnect layers 1606-1610 may have different compositions; in other embodiments, the composition of the dielectric material 1626 between different interconnect layers 1606-1610 may be the same.

A first interconnect layer 1606 (referred to as Metal 1 or “M1”) may be formed directly on the device layer 1604. In some embodiments, the first interconnect layer 1606 may include lines 1628a and/or vias 1628b, as shown. The lines 1628a of the first interconnect layer 1606 may be coupled with contacts (e.g., the S/D contacts 1624) of the device layer 1604.

A second interconnect layer 1608 (referred to as Metal 2 or “M2”) may be formed directly on the first interconnect layer 1606. In some embodiments, the second interconnect layer 1608 may include vias 1628b to couple the lines 1628a of the second interconnect layer 1608 with the lines 1628a of the first interconnect layer 1606. Although the lines 1628a and the vias 1628b are structurally delineated with a line within each interconnect layer (e.g., within the second interconnect layer 1608) for the sake of clarity, the lines 1628a and the vias 1628b may be structurally and/or materially contiguous (e.g., simultaneously filled during a dual damascene process) in some embodiments.

A third interconnect layer 1610 (referred to as Metal 3 or “M3”) (and additional interconnect layers, as desired) may be formed in succession on the second interconnect layer 1608 according to similar techniques and configurations described in connection with the second interconnect layer 1608 or the first interconnect layer 1606. In some embodiments, the interconnect layers that are “higher up” in the metallization stack 1619 in the IC device 1600 (i.e., farther away from the device layer 1604) may be thicker.

The IC device 1600 may include a solder resist material 1634 (e.g., polyimide or similar material) and one or more conductive contacts 1636 formed on the interconnect layers 1606-1610. In FIG. 7, the conductive contacts 1636 are illustrated as taking the form of bond pads. The conductive contacts 1636 may be electrically coupled with the interconnect structures 1628 and configured to route the electrical signals of the transistor(s) 1640 to other external devices. For example, solder bonds may be formed on the one or more conductive contacts 1636 to mechanically and/or electrically couple a chip including the IC device 1600 with another component (e.g., a circuit board). The IC device 1600 may include additional or alternate structures to route the electrical signals from the interconnect layers 1606-1610; for example, the conductive contacts 1636 may include other analogous features (e.g., posts) that route the electrical signals to external components.

In some embodiments in which the IC device 1600 is a double-sided die (e.g., like the base die 105), the IC device 1600 may include another metallization stack (not shown) on the opposite side of the device layer(s) 1604. This metallization stack may include multiple interconnect layers as discussed above with reference to the interconnect layers 1606-1610, to provide conductive pathways (e.g., including conductive lines and vias) between the device layer(s) 1604 and additional conductive contacts (not shown) on the opposite side of the IC device 1600 from the conductive contacts 1636.

In other embodiments in which the IC device 1600 is a double-sided die (e.g., like the base die 105), the IC device 1600 may include one or more TSVs through the die substrate 1602; these TSVs may make contact with the device layer(s) 1604, and may provide conductive pathways between the device layer(s) 1604 and additional conductive contacts (not shown) on the opposite side of the IC device 1600 from the conductive contacts 1636.

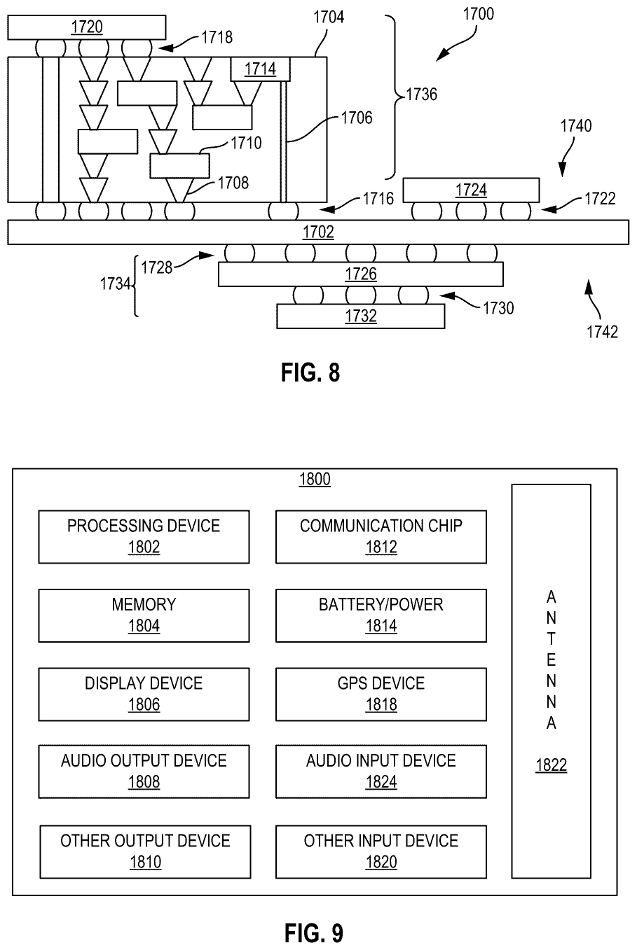

FIG. 8 is a cross-sectional side view of an IC device assembly 1700 that may include any of the microelectronic assemblies 100 disclosed herein. In some embodiments, the IC device assembly 1700 may be a microelectronic assembly 100. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. Any of the IC packages discussed below with reference to the IC device assembly 1700 may take the form of any suitable ones of the embodiments of the microelectronic assemblies 100 disclosed herein.

In some embodiments, the circuit board 1702 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate. In some embodiments the circuit board 1702 may be, for example, a circuit board.

The IC device assembly 1700 illustrated in FIG. 8 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 8), male and female portions of a socket, an adhesive, an underfill material, and/or any other suitable electrical and/or mechanical coupling structure.

The package-on-interposer structure 1736 may include an IC package 1720 coupled to an interposer 1704 by coupling components 1718. The coupling components 1718 may take any suitable form for the application, such as the forms discussed above with reference to the coupling components 1716. Although a single IC package 1720 is shown in FIG. 8, multiple IC packages may be coupled to the interposer 1704; indeed, additional interposers may be coupled to the interposer 1704. The interposer 1704 may provide an intervening substrate used to bridge the circuit board 1702 and the IC package 1720. The IC package 1720 may be or include, for example, a die (the die 1502 of FIG. 6), an IC device (e.g., the IC device 1600 of FIG. 7), or any other suitable component. Generally, the interposer 1704 may spread a connection to a wider pitch or reroute a connection to a different connection. For example, the interposer 1704 may couple the IC package 1720 (e.g., a die) to a set of ball grid array (BGA) conductive contacts of the coupling components 1716 for coupling to the circuit board 1702. In the embodiment illustrated in FIG. 8, the IC package 1720 and the circuit board 1702 are attached to opposing sides of the interposer 1704; in other embodiments, the IC package 1720 and the circuit board 1702 may be attached to a same side of the interposer 1704. In some embodiments, three or more components may be interconnected by way of the interposer 1704.

In some embodiments, the interposer 1704 may be formed as a PCB, including multiple metal layers separated from one another by layers of dielectric material and interconnected by electrically conductive vias. In some embodiments, the interposer 1704 may be formed of an epoxy resin, a fiberglass-reinforced epoxy resin, an epoxy resin with inorganic fillers, a ceramic material, or a polymer material such as polyimide. In some embodiments, the interposer 1704 may be formed of alternate rigid or flexible materials that may include the same materials described above for use in a semiconductor substrate, such as silicon, germanium, and other group III-V and group IV materials. The interposer 1704 may include metal interconnects 1708 and vias 1710, including but not limited to TSVs 1706. The interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 8 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 9 is a block diagram of an example electrical device 1800 that may include one or more of the microelectronic assemblies 100 disclosed herein. For example, any suitable ones of the components of the electrical device 1800 may include one or more of the IC device assemblies 1700, IC devices 1600, or dies 1502 disclosed herein, and may be arranged in any of the microelectronic assemblies 100 disclosed herein. A number of components are illustrated in FIG. 9 as included in the electrical device 1800, but any one or more of these components may be omitted or duplicated, as suitable for the application. In some embodiments, some or all of the components included in the electrical device 1800 may be attached to one or more motherboards. In some embodiments, some or all of these components are fabricated onto a single system-on-a-chip (SoC) die.

Additionally, in various embodiments, the electrical device 1800 may not include one or more of the components illustrated in FIG. 9, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices. The electrical device 1800 may include a memory 1804, which may itself include one or more memory devices such as volatile memory (e.g., dynamic RAM (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic RAM (eDRAM) or spin transfer torque magnetic RAM (STT-MRAM).

In some embodiments, the electrical device 1800 may include a communication chip 1812 (e.g., one or more communication chips). For example, the communication chip 1812 may be configured for managing wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMLS), High Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any device that generates an audible indicator, such as speakers, headsets, or earbuds.

The electrical device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The electrical device 1800 may include a GPS device 1818 (or corresponding interface circuitry, as discussed above). The GPS device 1818 may be in communication with a satellite-based system and may receive a location of the electrical device 1800, as known in the art.

The electrical device 1800 may include an other output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include an other input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1800 may have any desired form factor, such as a computing device or a hand-held, portable or mobile computing device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server, or other networked computing component, a printer, a scanner, a monitor, a set-top box, an entertainment control unit, a vehicle control unit, a digital camera, a digital video recorder, or a wearable computing device. In some embodiments, the electrical device 1800 may be any other electronic device that processes data.

The following paragraphs provide various examples of the embodiments disclosed herein.
Example 1 is a microelectronic assembly, including a first die having a first surface, an opposing second surface, and a first footprint; a second die electrically coupled to the second surface of the first die and having a second footprint, wherein the second footprint is smaller than the first footprint; and a mold material on the second surface of the first die and surrounding the second die, the mold material including a trench.
Example 2 may include the subject matter of Example 1, and may further specify that a thickness of the trench is less than a thickness of the mold material.
Example 3 may include the subject matter of Examples 1 or 2, and may further specify that a width of the trench is between 50 microns and 300 microns.
Example 4 may include the subject matter of any of Examples 1-3, and may further specify that the trench is located at least 50 microns from an outside edge of the mold material and at least 50 microns from an outside edge of the second die.
Example 5 may include the subject matter of any of Examples 1-4, and may further specify that the trench is in a corner portion of the mold material.
Example 6 may include the subject matter of Example 5, and may further specify that the corner portion of the mold material has a length greater than or equal to 200 microns and a width greater than or equal to 200 microns.
Example 7 may include the subject matter of any of Examples 1-6, and may further specify that the trench is one of a plurality of trenches.
Example 8 may include the subject matter of Example 7, and may further specify that the plurality of trenches is arranged in a grid pattern.
Example 9 may include the subject matter of Example 1, and may further specify that the trench is in a portion of the mold material having a length greater than or equal to 200 microns and a width greater than or equal to 200 microns, and wherein a total volume of the trench is equal to between 10 percent and 50 percent of a total volume of the portion of the mold material.
Example 10 is a microelectronic assembly, including a first die having a first surface, an opposing second surface, and a first footprint; a second die electrically coupled to the second surface of the first die and having a second footprint, wherein the second footprint is smaller than the first footprint; and an insulating material on the second surface of the first die and surrounding the second die, the insulating material including a plurality of trenches configured to mitigate warpage of the first die and second die.
Example 11 may include the subject matter of Example 10, and may further specify that the plurality of trenches is along a perimeter of the insulating material.
Example 12 may include the subject matter of Example 10, and may further specify that the plurality of trenches is in a corner portion of the insulating material.
Example 13 may include the subject matter of Example 12, and may further specify that the corner portion of the insulating material has a length greater than or equal to 200 microns and a width greater than or equal to 200 microns.
Example 14 may include the subject matter of any of Examples 10-13, and may further specify that the plurality of trenches is arranged in an intersecting pattern.
Example 15 may include the subject matter of any of Examples 10-13, and may further specify that the plurality of trenches is arranged in a non-intersecting pattern.
Example 16 may include the subject matter of any of Examples 10-15, and may further include a package substrate electrically coupled to the first surface of the first die.
Example 17 may include the subject matter of any of Examples 10-16, and may further specify that the insulating material is a mold material.
Example 18 may include the subject matter of Example 17, and may further specify that the mold material includes filler particles.
Example 19 is a microelectronic assembly, including a first die having a first surface and an opposing second surface; a second die electrically coupled to the second surface of the first die; a third die electrically coupled to the second surface of the first die; a mold material on the second surface of the first die and surrounding the second die and the third die, the mold material including a portion of mold material, surrounding the second die and the third die, having a length greater than or equal to 200 microns and a width greater than or equal to 200 microns; and a trench in the portion of mold material.
Example 20 may include the subject matter of Example 19, and may further specify that the portion of mold material is along a perimeter or in a corner of the mold material.
Example 21 may include the subject matter of Examples 19 or 20, and may further specify that a width of the trench is between 50 microns and 300 microns.
Example 22 may include the subject matter of any of Examples 19-21, and may further specify that the trench is one of a plurality of trenches.
Example 23 may include the subject matter of any of Examples 19-22, and may further specify that the trench is filled with one or more of a capillary underfill, a self-healing polymer, a porous dielectric, and an elastomer.

1. A microelectronic assembly, comprising:
a first die having a first surface, an opposing second surface, and a first footprint;
a second die electrically coupled to the second surface of the first die and having a second footprint, wherein the second footprint is smaller than the first footprint; and
a mold material on the second surface of the first die and surrounding the second die, the mold material including a trench.

2. The microelectronic assembly of claim 1, wherein a thickness of the trench is less than a thickness of the mold material.

3. The microelectronic assembly of claim 1, wherein a width of the trench is between 50 microns and 300 microns.

4. The microelectronic assembly of claim 1, wherein the trench is located at least 50 microns from an outside edge of the mold material and at least 50 microns from an outside edge of the second die.

5. The microelectronic assembly of claim 1, wherein the trench is in a corner portion of the mold material.

6. The microelectronic assembly of claim 5, wherein the corner portion of the mold material has a length greater than or equal to 200 microns and a width greater than or equal to 200 microns.

7. The microelectronic assembly of claim 1, wherein the trench is one of a plurality of trenches.

8. The microelectronic assembly of claim 7, wherein the plurality of trenches is arranged in a grid pattern.

9. The microelectronic assembly of claim 1, wherein the trench is in a portion of the mold material having a length greater than or equal to 200 microns and a width greater than or equal to 200 microns, and wherein a total volume of the trench is equal to between 10 percent and 50 percent of a total volume of the portion of the mold material.

10. A microelectronic assembly, comprising:
a first die having a first surface, an opposing second surface, and a first footprint;
a second die electrically coupled to the second surface of the first die and having a second footprint, wherein the second footprint is smaller than the first footprint; and
an insulating material on the second surface of the first die and surrounding the second die, the insulating material including a plurality of trenches configured to mitigate warpage of the first die and second die.

11. The microelectronic assembly of claim 10, wherein the plurality of trenches is along a perimeter of the insulating material.

12. The microelectronic assembly of claim 10, wherein the plurality of trenches is in a corner portion of the insulating material.

13. The microelectronic assembly of claim 12, wherein the corner portion of the insulating material has a length greater than or equal to 200 microns and a width greater than or equal to 200 microns.

14. The microelectronic assembly of claim 10, wherein the plurality of trenches is arranged in an intersecting pattern.

15. The microelectronic assembly of claim 10, wherein the plurality of trenches is arranged in a non-intersecting pattern.

16. A microelectronic assembly, comprising:
a first die having a first surface and an opposing second surface;
a second die electrically coupled to the second surface of the first die;
a third die electrically coupled to the second surface of the first die;
a mold material on the second surface of the first die and surrounding the second die and the third die, the mold material including a portion of mold material, surrounding the second die and the third die, having a length greater than or equal to 200 microns and a width greater than or equal to 200 microns; and
a trench in the portion of mold material.

17. The microelectronic assembly of claim 16, wherein the portion of mold material is along a perimeter or in a corner of the mold material.

18. The microelectronic assembly of claim 16, wherein a width of the trench is between 50 microns and 300 microns.

19. The microelectronic assembly of claim 16, wherein the trench is one of a plurality of trenches.

20. The microelectronic assembly of claim 1, wherein the trench is filled with one or more of a capillary underfill, a self-healing polymer, a porous dielectric, and an elastomer.
